(19) United States
(12) Patent Application Publication
(10) Pub. No.: US 2005/0034672 A1
(43) Pub. Date: Feb. 17, 2005

(54) Evaporation source for deposition process and insulation fixing plate, and heating wire winding plate and method for fixing heating wire

(76) Inventors: Jae-Gyoung Lee, Seongnam (KR); Shin-Cheul Kim, Koyang (KR); Noh-Hoon Myoung, Anseong (KR)

Correspondence Address: ST. ONGE STEWARD JOHNSTON & REENS, LLC, 986 BEDFORD STREET, STAMFORD, CT, 06905-5619, US

(21) Appl. No.: 10/943,486

(22) Filed: Sep. 17, 2004

Related U.S. Application Data
(63) Continuation of application No. PCT/KR03/00525, filed on Mar. 18, 2003.

(30) Foreign Application Priority Data
Mar. 19, 2002 (KR) 2002/14703
Mar. 19, 2002 (KR) 2002/14704

(51) Int. Cl. C23C 16/00

(52) U.S. Cl. 118/726

(57) ABSTRACT

Disclosed is a linear evaporation source used for forming a thin film for an organic semiconductor device, the linear evaporation source comprising a crucible having a receiving space formed therein, for accommodating an evaporation material and an opening section formed at one side of the crucible in a length direction, wherein the opening section becomes narrow as it travels from both ends to a center portion thereof. If the thin film is formed using the linear evaporation source, a low material use rate of the vacuum evaporation source for the formation of the thin film is improved, thickness uniformity of the deposited thin film throughout the whole area is secured, and shadow effect due to the shadow mask is improved.

This application is a continuation of pending International Patent Application No. PCT/KR2003/000525 filed Mar. 18, 2003 which designates the United States and claims priority of pending Korean Patent Application Nos. 2002-14703 and 2002-14704 filed Mar. 19, 2002.

### FIELD OF INVENTION

The present invention relates to an evaporation source for a deposition process and insulation fixing plate, and a heating wire winding plate and a method for fixing a heating wire, and more particularly, to an evaporation source for a deposition process in which a low material use rate is improved and thickness uniformity of a deposited thin film throughout the whole area is secured.

Further, the present invention is directed to an insulation fixing plate, heating wire winding plate and method for fixing a heating wire in which the heating wire arranged and fixed on an evaporation source used to form a thin film of semiconductor or the like using a deposition process, is prevented from being damaged, the heating wire is easily installed around the evaporation source to apply heat to the evaporation source uniformly, endurance property of the heating wire is enhanced, and the area shielded by the fixing plate for fixing the heating wire is minimized to enhance the efficiency.

### BACKGROUND ART

Generally, an organic semiconductor device including the organic electroluminescence (EL) device or the like can be fabricated by two methods. One is to evaporate a low molecule material in a vacuum and the other is to dissolve a high polymer material in a solvent and coat the dissolved high polymer solution by using spin coating, dip coating, doctor blading, ink-jet printing or the like.

In the aforementioned methods, when a thin film is formed in a vacuum state, a shadow mask having an opening of a desired shape is aligned in front of a substrate to deposit the thin film on the substrate through the shadow mask.

In case of the aforementioned vacuum deposition method, in order to secure the thickness uniformity of the thin film, the substrate 1 is distanced from an evaporation source 2, and the evaporation source 2 is located below the center of the substrate 1 as shown in FIG. 1. After that, the thin film is deposited while the substrate 1 is rotated.

As an improvement of the above method, as shown in FIG. 2, the evaporation source 2 is located below the substrate 1 at an inclination angle. After that, the thin film is deposited while the substrate 1 is rotated, to thereby enhance the uniformity of the thin film.

However, the aforementioned deposition methods cause several problems as the substrate size increases. In other words, as the substrate size increases, the distance between the substrate 1 and the evaporation source 2 increases too. Owing to the increase in the distance between the substrate 1 and the evaporation source 2, the material evaporated from the evaporation source 2 is naturally deposited on the substrate 1 but its much portion is deposited even on the vacuum chamber, so that the use rate of the evaporation source material is remarkably lowered. Considering that the organic material in a practical use is expensive, undesired deposition on the vacuum chamber acts as a great factor affecting on the elevation in the fabrication costs.

Further, as the substrate has a large size, as shown in FIG. 3, a shadow effect (‘a’ of FIG. 3) caused by an angle between the shadow mask 3 and the evaporation source 2 is problematic. The shadow effect is caused because an angle between the substrate 1 and the evaporation 2 at the central portion of the substrate 1 is different than an angle between an angle between the substrate 1 and the evaporation 2 at the edge portion of the substrate 1. This problem is more serious in fabricating a natural color device which the opening of the shadow mask decreases much more.

To aforementioned shadow effect problem, there is proposed a method in which a plurality of evaporation sources are linearly arranged or a method which the substrate is scanned using a linear evaporation source.

However, in the case of using a plurality of evaporation sources, it is not easy to control the evaporation rate at a desired value by controlling the respective evaporation sources. Also, in the case of using the linear evaporation source, it is not easy to solve the non-uniformity of the thin film which is generated at an edge portion of the substrate.

In the meanwhile, the evaporation sources used in a vacuum state for a deposition process is generally divided into the heating evaporation source in which the evaporation material is evaporated by a direct resistance heating and the radiation evaporation source in which the evaporation material is evaporated by the radiation generated from the heating wire.

FIG. 4 is a perspective view of the heating wire fixing device in the conventional radiation evaporation source.

As shown in FIG. 4, a heating wire 32 is arranged around a crucible 31 in which an evaporation material is received. While this example shows the crucible 31 corresponding to a point source, it will be apparent to those skilled in the art that the example can be also applied to a crucible corresponding to a linear source.

To fix the heating wire 32, insulation fixing plates 33 and 34 made of ceramics are arranged at upper end and lower end of the crucible 31 and the heating wire 32 is inserted alternatively into holes 33a and 34a. In the case of using a high temperature evaporation source, a metal plate (not shown) is arranged around an outer circumference of the insulation fixing plates 33 and 34 to reflect the heat radiated from the heating wire.

Thus, in order to arrange the heating wire 32 by using the upper and lower insulation fixing plates 33 and 34, the upper and lower insulation fixing plates 33 and 34 are arranged such that their holes 33a and 34a face and correspond to each other. Then, the long heating wire 32 is passed through the upper hole 33a of the upper insulation fixing plate 33 and the lower hole 34a of the lower insulation fixing plate 34 sequentially. The heating wire is inserted into the hole 34a adjacent to the previous lower hole 34a through which the heating wire 32 was passed and is then inserted into the hole 33a adjacent to the previous upper hole 33a in an opposite direction to the previous insertion direction. By repeating the aforementioned procedure, the heating wire 32 is inserted into all the upper and lower holes 33a and 34a and is then fixed as shown in FIG. 4.

In the above procedure, after the heating wire 32 is passed through the adjacent hole, it is pulled to a tight state to prevent the heating wire from being opened and apply heat uniformly. Then, during pulling the heating wire 32, the heat wire 32 may be damaged due to a friction with the holes of the insulation fixing plates or be curved.

If the evaporation source is fabricated in a state that the heating wire is damaged as aforementioned, and current flows through the heating wire, the temperature distribution of the crucible is not uniform due to partly non-uniform resistances of the heating wire. If the heating wire is used in such a state for a long-term period, the mechanical strength at the damaged portion is weakened, so that an opening of the heating wire may be caused.

Also, the aforementioned conventional heating wire fixing device shields the heating wire by the thickness of the upper and lower insulation fixing plates, so that the radiation heat applied to the crucible decreases correspondingly.

### DISCLOSURE OF THE INVENTION

Accordingly it is an object of the present invention to provide a linear evaporation source used for forming a thin film for an organic semiconductor device in which a low material use rate is improved, thickness uniformity of a deposited thin film throughout the whole area is secured, and shadow effect due to the shadow mask is improved.

It is another object of the invention to provide a heating wire winding plate and method for fixing a heating wire in which a damage of the heating wire is prevented, the heating wire is easily installed around the evaporation source to apply heat to the evaporation source uniformly, endurance property of the heating wire is enhanced, and the area shielded by the fixing plate for fixing the heating wire is minimized to enhance the deposition efficiency.

To achieve these objects and other advantages and in accordance with the purpose of the invention, as embodied and broadly described herein, there is provided a linear evaporation source used for forming a thin film for an organic semiconductor device, the linear evaporation source comprising a crucible having a receiving space formed therein, for accommodating an evaporation material and an opening section formed at one side of the crucible in a length direction, wherein the opening section becomes narrow as it travels from both ends to a center portion thereof.

The center portion of the opening section may be partially closed in the length direction.

In an aspect of the invention, there is provided a linear evaporation source used for forming a thin film for an organic semiconductor device, the linear evaporation source comprising: a crucible having a receiving space for accommodating an evaporation material therein and of which one side is opened; and an opening adjusting unit having an opening of which width becomes narrow as it travels from both ends to the center portion, the opening adjusting unit being separatably inserted into the crucible at the one side.

Preferably, the crucible is partly removed at an overlapping portion with the opening adjusting unit so that a part of the opening adjusting unit is exposed to a heating source.

Also, a splash preventive section for preventing the evaporation material from being discharged to an outside may be formed at a lower portion of the opening within the receiving space.

Preferably, a plurality of blocks for dividing the receiving space and receiving the evaporation material therein may be arranged at regular intervals in the length direction within the receiving space.

In an aspect of the invention, there is provided a linear evaporation source used for forming a thin film for an organic semiconductor device, the linear evaporation source comprising a crucible having a receiving space formed therein, for accommodating an evaporation material and an opening section formed at one side of the crucible in a length direction, wherein the opening section is formed such that width thereof becomes narrow as it travels from both ends to the center portion, and wherein the crucible further comprises a splash preventive section formed protrudedly from a lower side portion of the opening within the receiving space.

In an aspect of the invention, there is provided a linear evaporation source assembly used for forming a thin film for an organic semiconductor device, the linear evaporation source assembly comprising: a crucible having a receiving space formed therein, for accommodating an evaporation material and an opening section formed at one side of the crucible in a length direction; and a heating unit installed to be associated with the crucible, for evaporating the evaporation material, wherein the opening section is formed such that width thereof becomes narrow as it travels from both ends to the center portion.

In an aspect of the invention, there is provided an insulation fixing plate for fixing a heating wire in a deposition evaporation source, the insulation fixing plate comprising: a frame forming a closed loop; and a plurality of protrusions formed integrally with and protrudedly from the frame toward the center of the frame, the plurality of protrusions being spaced apart by regular clearances from one another, wherein each of the plurality of protrusions has a groove formed in an upper surface thereof and on which a heating wire is hung.

Preferably, the frame has a passing groove through which the heating wire passes at a portion of the clearance which meets with the groove.

Alternatively, the insulation fixing plate may further include: a hanging jaw formed at an outer end of the frame; and a radiation plate of which both ends are fixed between the hanging jaw and the outer end.

In an aspect of the invention, there is provided a heater assembly of a deposition evaporation source comprising: a pair of insulation fixing plates arranged apart by a constant interval from each other in a longitudinal direction, for fixing a heating wire in an evaporation source for a deposition, the insulation fixing plate including: (a) a frame forming a closed loop; and (b) a plurality of protrusions formed integrally with and protrudedly from the frame toward the center of the frame, the plurality of protrusions being spaced apart by regular clearances from one another, wherein each of the plurality of protrusions has a groove formed in an upper surface thereof and on which a heating wire is hung; a heating wire passing through the clearances of the pair of insulation fixing plates and wound in a zigzag in upward and downward directions with the grooves as a boundary.

In an aspect of the invention, there is provided a heating wire winding plate of a deposition evaporation source, which is provided such that the heating wire is wound on the aforementioned insulation fixing plate, the heating wire winding plate comprising a plurality pairs of pin grooves into which pins are inserted and arranged in two columns at regular intervals, wherein the pin grooves arranged in one column are arranged in a zigzag to face regions between the pin grooves in the other column, and the width between the pin grooves corresponds to the width of the protrusion of the insulation fixing plate.

Alternatively, the heating wire winding plate may further include another pin grooves extended and spaced by a predetermined distance from either one of the two columns.

Preferably, the heating wire winding plate may further include a fixing groove formed adjacent to the pin grooves formed at an end thereof and into which a fixing piece for fixing a front end of the heating wire is inserted.

In an aspect of the invention, there is provided a method for fixing a heating wire of a deposition evaporation source, the heating wire being installed at and fixed to the evaporation source by using the insulation fixing plate of claim 13 and the heating wire winding plate of claim 18, the method comprising the steps of: inserting the pins into the pin grooves of the heating wire winding plate and fixing the front end of the heating wire at a position adjacent to the pin on which the heating wire is wound for the first time; winding the heating wire in a zigzag between one column and another column facing the one column with the inserted pins as a boundary; separating the winding-completed heating wire from the heating wire winding plate; hanging bent portions of the separated heating wire on the grooves of the protrusions of the insulation fixing plate; and pulling and arranging the pair of insulation fixing plates on which the heating wire is wound so as to have a constant tension, and installing the pair of insulation fixing plates at the evaporation source.

Preferably, the fixing method, after the step of installing the pair of insulation fixing plates at the evaporation source, further include the step of installing a radiation plate between the pair of insulation fixing plates in an outward direction of the heating wire.

It is to be understood that both the foregoing general description and the following detailed description are exemplary and explanatory and are intended to provide further explanation of the invention as claimed.

### BRIEF DESCRIPTION OF DRAWINGS

The accompanying drawings, which are included to provide a further understanding of the invention and are incorporated in and constitute a part of this specification, illustrate embodiments of the invention and together with the description serve to explain the principles of the invention.

In the drawings:

FIG. 1 shows a deposition method using a conventional evaporation source;

FIG. 2 shows another deposition method using a conventional evaporation source;

FIG. 3 illustrates a shadow effect caused when a thin film is deposited using a conventional evaporation source;

FIG. 4 is a perspective view of a heating wire fixing device of a conventional radiation evaporation source;

FIG. 5 is a perspective view of a linear evaporation source for the fabrication of a thin organic semiconductor device according to a first embodiment of the present invention;

FIG. 6 is a side sectional view of the linear evaporation source of FIG. 5;

FIG. 7a is a side sectional view of a linear evaporation source for the fabrication of a thin organic semiconductor device according to a second embodiment of the present invention;

FIG. 7b is a side sectional view of FIG. 6a;

FIG. 8 is a sectional view of a linear evaporation source for the fabrication of a thin organic semiconductor device according to a third embodiment of the present invention;

FIG. 9 shows a deposition method of a thin film using a linear evaporation source of the present invention;

FIG. 10 is another deposition method of a thin film using a linear evaporation source of the present invention;

FIG. 11 is a sectional view of a linear evaporation source for the fabrication of a thin organic semiconductor device according to a fourth embodiment of the present invention;

FIG. 12 shows a deposition method of a thin film using the linear evaporation source of FIG. 11;

FIG. 13 is a graph showing the thickness uniformity of a thin film when a linear evaporation source for the fabrication of a thin organic semiconductor device according to the present invention is used;

FIG. 14 is a perspective view showing an installation state of the heating wire in an evaporation source for the deposition process of the present invention;

FIG. 15 is a plan view of an insulation fixing plate of the heating wire fixing device in an evaporation source for the deposition process of the present invention;

FIG. 16 is a sectional view taken along the line A-A′ of FIG. 3;

FIG. 17 is a sectional view of another insulation fixing plate of the heating wire fixing device in an evaporation source for the deposition process of the present invention;

FIG. 18 is a plan view of a heating wire winding plate of the heating wire fixing device in an evaporation source for the deposition process of the present invention; and

FIG. 19 is a disassembled perspective view showing the heating wire using the heating wire winding plate of the heating wire fixing device in an evaporation source for the deposition process of the present invention.

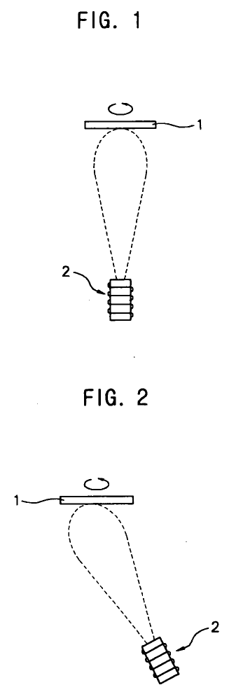

### DETAILED DESCRIPTION OF EMBODIMENTS

Reference will now be made in detail to the preferred embodiments of the present invention, examples of which are illustrated in the accompanying drawings.

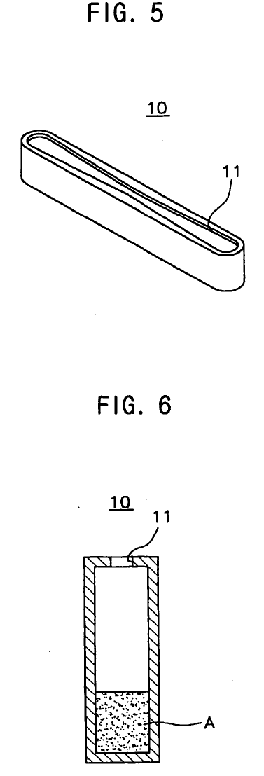

FIG. 5 is a perspective view of a linear evaporation source for the fabrication of a thin organic semiconductor device according to a first embodiment of the present invention, and FIG. 6 is a side sectional view of the linear evaporation source of FIG. 5.

A crucible 10 has an opening 11 formed at one side thereof. The other side of the crucible 10 is closed to form a receiving space. A deposition material (A) is received in the receiving space. Preferably, the crucible 10 is shaped in a long cylinder, and the opening 11 is formed in the length direction of the crucible 10.

Hence, it is possible to deposit a thin film by moving a substrate in a direction normal to the length direction over the opening 11 or inversely moving the crucible 10.

According to the present invention, the width of the opening 11 is made to be narrow when it travels from the both ends of the crucible 10 to the center portion in the length direction, so that it becomes possible to deposit a thin film at a uniform thickness.

In other words, in the conventional art, since the width of the opening 11 is the same throughout the whole length of the crucible 10, deposited film is formed comparatively thick at the center portion but formed comparatively thin as it travels to the periphery of the substrate. As a result, the uniformity of the thin film is lowered on the whole.

Also, if the center portion of the opening 11 is partly closed, it is possible to obtain the same effect.

It will be apparent to those skilled in the art that various modifications and variations of the aforementioned basic characteristic can be made therein without departing from the spirit and scope of the invention. For instance, the opening 11 can be made in a circular shape or a rectangular shape to be spaced from each other in the length direction such that the size decreases as it travels to the center portion.

In addition, there can be formed a main opening having the same width in the length direction and triangular auxiliary openings arranged at both sides of the main opening, each of which width except for the a certain portion of the center portion decreases as it travels to the center portion.

Linear Evaporation Source According to Second Embodiment

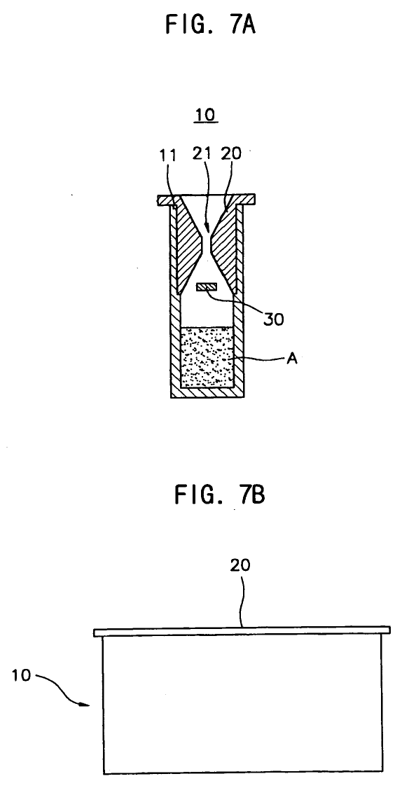

As shown in FIGS. 7a and 7b, an opening 11 is formed in a constant size in the length direction and an opening adjusting unit 20 having a nozzle section 21 of which width is the same in its shape as that of the first embodiment is separatably installed to enable an easy adjustment of the opening area.

Generally, since it is not easy to form an opening having the same shape as that of the first embodiment, the opening adjusting unit 20 is detachably fabricated and is attached to the opening 11 of the crucible 10.

The opening adjusting unit 20 can be fabricated integrally as one set or two or more openings can be separatably fabricated and installed in a combination. Preferably, a flange is formed at an upper end of the opening adjusting unit 20 so that it is possible to precisely set a depth closely inserted to the upper end of the crucible 10.

Also, a splashing preventive piece 30 is installed spaced by a constant distance from the nozzle section 21 at a lower portion of the crucible 10 such that it is prevented that the material (A) in the crucible 10 is splashed to damage a substrate or the like.

Linear Evaporation Source According to Third Embodiment

In case the aforementioned second embodiment utilizes the opening adjusting unit 20, the opening adjusting unit 20 is inserted into the crucible 10 to function to shield heat so that relative temperature of the opening is lowered and thus the deposition material may be deposited on the opening adjusting unit 20. In such a case, while the deposition proceeds, there may be caused a result that the deposition material deforms the shape of the opening of the opening adjusting unit 20 and further closes the entrance.

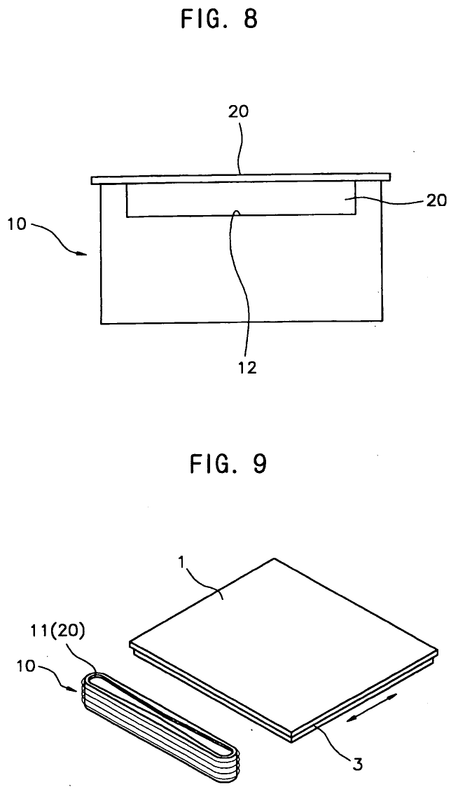

To improve this drawback, as shown in FIG. 8, both side portions of the crucible 10 are partially dug to expose the opening adjusting unit 20 so that the exposed portion forms a heating section 12 to allow the heat of the heating wire upon deposition to heat the opening adjusting unit 20 directly and prevent the deposition material (A) from being deposited on the opening adjusting unit 20 and the entrance from being closed.

FIG. 9 shows a deposition method of a thin film using a linear evaporation source of the present invention. Operation and effect of the invention will be described with reference to FIGS. 5 to 9.

As shown in FIG. 9, in case of using a linear evaporation source of the invention, deposition is preferably performed by linearly moving a substrate 1 and a mask 3 with respect to the length direction of the opening 11 of the crucible 10, but sometimes it may be performed by linearly moving the crucible 10 in a state that the substrate 1 and the mask 3 are fixed.

The opening 11 of the crucible 10 may have various shapes if it is made such that the width decreases as it travels from both ends to the center portion. In other words, if both edge portions have a triangular shape and a passage between an apex of the triangle of one edge portion and the center portion of the opening extends to an apex of the triangle of the other edge portion, the same effect can be obtained and the thickness uniformity of the thin film can be greatly enhanced.

Also, as shown in FIGS. 7a and 7b, it is possible to easily control the area of the opening 11 through which the material (A) is evaporated by attaching the separate opening adjusting unit 20 to the opening 11. The opening adjusting unit 20 can be made attachably and detachably so that when the nozzle section 21 is contaminated by the deposition of the material (A) and thus the opening area is narrowed, it can be easily separated and cleaned.

In the meanwhile, in case the deposition starts for the first time or material density is varied, the material (A) is splashed to contaminate the substrate 1 or an unpredictable deposition may be performed, which causes a great damage of the deposited thin film. Accordingly, the splashing preventive piece 30 is provided to prevent such problems.

First of all, in case of depositing a thin film using the conventional evaporation source, it is requested that the substrate 1 be distanced from the evaporation source for the thickness uniformity of the thin film deposited. However, in case of using the linear evaporation source of the invention, since it is possible to perform the deposition in a state that the substrate 1 approaches the evaporation source comparatively, the use period of the material (A) is greatly enhanced so that it is unnecessary to replenish the deposition source frequently.

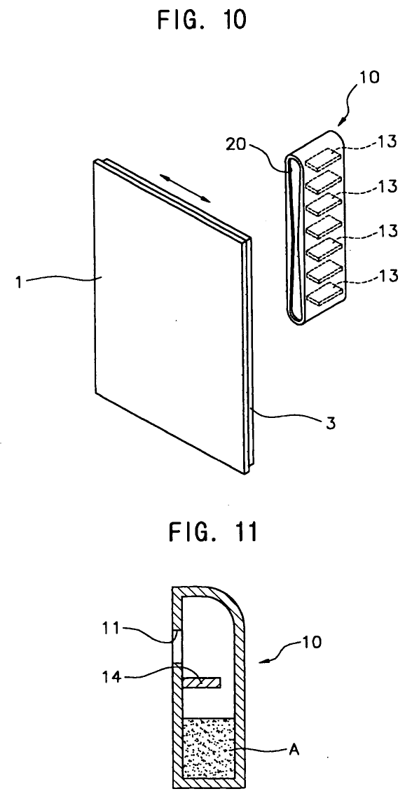

Meanwhile, as shown in FIG. 10, sometimes, the deposition may be performed by moving the substrate 1 and the mask 3 in the left and right directions in a state the substrate 1 and the mask 3 are stood up in the length direction and the crucible 10 is arranged in the length direction.

In the above case, if the crucible has a general shape, the material is biased downward and thus the deposition material flows down. Or, although it is possible to form a thin film, the thickness uniformity of the thin film cannot be guaranteed. To solve the aforementioned drawback, blocks 13 are installed at the inner space where the deposition material is received, in the form of a drawer which the opening and closing are possible. As a result, it can be prevented that the deposition material is biased downward.

Linear Evaporation Source According to Fourth Embodiment

Referring to FIG. 11, in case the substrate 1 and the mask 3 are stood up, an opening 11 formed at a side portion facing the substrate 1 and a splash preventive section 14 for preventing material (A) from being splashed is formed within a crucible 10.

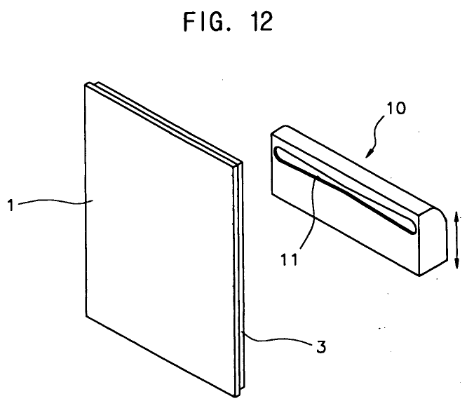

As shown in FIG. 12, deposition is performed by moving the crucible 10 up and down in a state that the substrate 1 and the mask 3 are stood up.

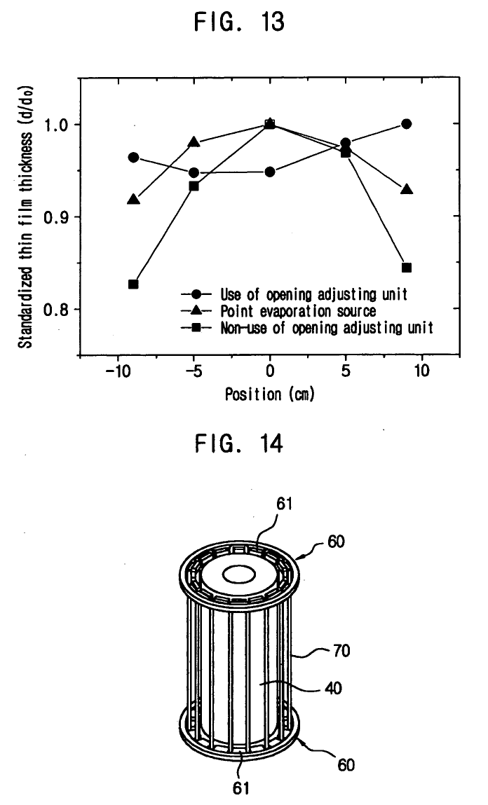

FIG. 13 is a graph showing the thickness uniformity of a thin film when a linear evaporation source for the fabrication of a thin organic semiconductor device according to the present invention is used. As shown in FIG. 13, the examples (●) that a thin film is formed by using a linear evaporation source of the invention show improved thickness uniformity compared with the examples (▴) that a thin film is formed by using a point evaporation source and examples (▪) that a thin film is formed without using the opening adjusting unit.

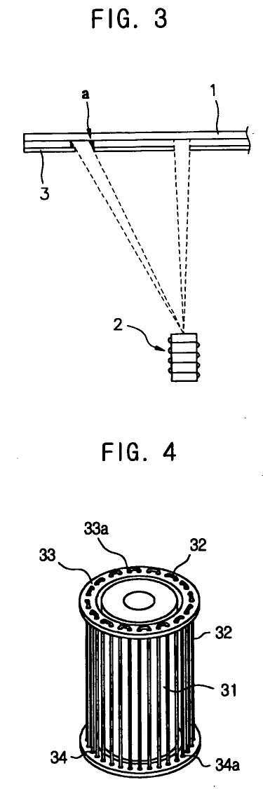

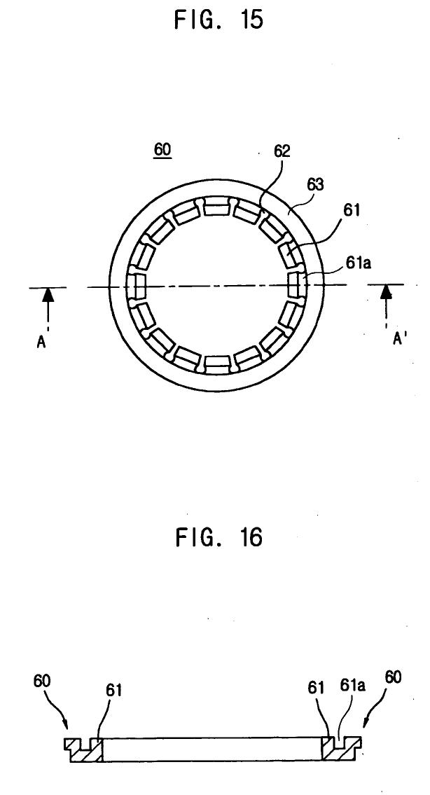

FIG. 14 is a perspective view showing an installation state of the heating wire in an evaporation source for the deposition process of the present invention, FIG. 15 is a plan view of an insulation fixing plate of the heating wire fixing device in an evaporation source for the deposition process of the present invention, and FIG. 16 is a sectional view taken along the line A-A′ of FIG. 3.

For the convenience of the description, the present embodiment is described with an example of the point evaporation source, and it will be apparent that the present embodiment can be applied to the linear evaporation sources of the first to fourth embodiments.

Heating wires 70 are arranged at regular intervals around a point evaporation source 40 to enclose the point evaporation source 40.

The heating wires 70 have both ends fixed by insulation fixing plates 60 arranged at both ends of the point evaporation source 40.

Referring to FIGS. 15 and 16, the insulation fixing plate 60 includes a ring-shaped frame 63, and a plurality of protrusions 61 integrally protruded from the frame 63 toward the center. In the upper surfaces of the protrusions 61, grooves 61a are respectively formed to guide the heating wire 70 therein and fix. A plurality of passing grooves 62 having a diameter to permit the passing of the heating wire 70 is formed.

Preferably, the protrusions 61 are formed separatably at regular intervals and circular passing grooves 62 are formed at places where the heating wire passes so as not to damage the heating wire even through friction is generated due to the movement of the heating wire 70.

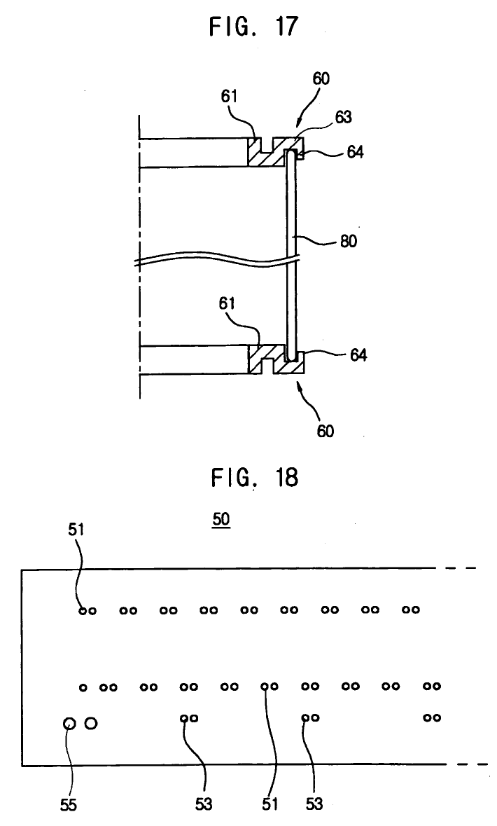

FIG. 17 is a sectional view of another insulation fixing plate of the heating wire fixing device in an evaporation source for the deposition process of the present invention.

A hanging jaw 64 is formed at an outer end of the frame 63 of the insulation fixing plate 60 to fix both ends of a radiation plate 80. In other words, to obtain a high radiation temperature, the radiation plate 80 is installed to enclose the heating wire 70. The hanging jaw 64 formed at the outer end of the frame 63 allows the radiation plate 70 to be installed more easily.

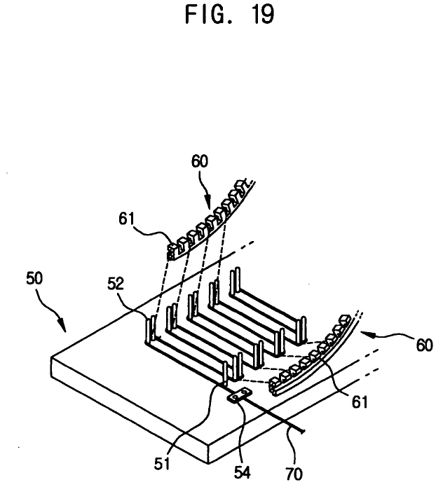

FIG. 18 is a plan view of a heating wire winding plate of the heating wire fixing device in an evaporation source for the deposition process of the present invention.

In order to install the heating wire 70 more easily at the evaporation source 40 by using the insulation fixing plate 60 of the invention, a heating wire winding plate 50 is used. A plurality pairs of pin grooves 51 through which pins (52 of FIG. 19) are inserted are arranged in two columns on the heating wire winding plate 50. The interval between the respective pairs of pin grooves 51 corresponds to the width of the protrusion 61, and the interval between the columns corresponds to the interval between the upper and lower insulation fixing plates 60.

The respective pairs of pin grooves 51 in one column are preferably arranged to face regions between the respective pairs of pin grooves in the other column such that the heating wire 70 is wound in a zigzag type.

Also, it is possible that the pin grooves 51 are formed to have a width corresponding to the width of the protrusions 61 and are arranged one by one. At this time, the circumference of the pins inserted into the pin grooves 51 is preferably made in a round shape so as to minimize the friction between the heating wire and the pins while the heating wire is wound.

In addition, fixing grooves 55 correspond to a portion into which a fixing piece (54 of FIG. 19) for fixing a front end of the heating wire 70 is inserted, and they are formed at a plurality of locations so as to wind the heating wire depending on the size of the evaporation source to install the heating wire.

FIG. 19 is a disassembled perspective view showing a winding method of the heating wire using the heating wire winding plate of the heating wire fixing device in an evaporation source for the deposition process of the present invention.

First, there will be a procedure in which the heating wire is installed at the evaporation source by using the heating wire winding plate with reference to FIGS. 18 and 19.

As shown in FIG. 19, the pins 52 are inserted into the pin grooves 51 of the heating wire winding plate 50, the heating wire 70 is passed between the fixing grooves 55, and a fixing piece 54 is inserted into and fixed to the fixing grooves 55 such that the heating wire maintains a constant tension.

Thereafter, the heating wire 70 is repeatedly wound around the pins 52 in a zigzag type with putting the respect pins 52 as a boundary.

After the heating wire is wound completely, the fixing piece 54 is removed and the pins 52 are separated from the pin grooves 51, so that the heating wire 70 wound in a predetermined shape is separated from the heating wire winding plate 50. In other words, since the heating wire 70 has a constant diameter, it still maintains the shape as wound.

In this state, the heating wire is hung on the upper and lower insulation plates 60 such that the bent portions of the heating wire 70 by the respective pins 52 are hung on the grooves 61a of the protrusions 61.

After that, the two insulation plates 60 are pulled to have a constant tension by a height of the evaporation source intended for the installation, and then the two insulation fixing plates 60 are installed at the evaporation source.

As mentioned above, the present invention is characterized in that the heating wire is wound using the heating wire winding plate to maintain a predetermined shape, and the heating wire wound on the protrusions of the insulation fixing plate is moved and installed at the evaporation source. By the aforementioned installation method, an excess friction or tension does not act on the heating wire and an easy installation of the heating wire becomes possible.

In the meanwhile, if necessary, the invention may be configured to have a difference between the radiation heats applied to the upper and lower sides of the evaporation source. In particular, there are many cases that the lower side of the evaporation source is made to have a higher temperature than the upper side. In such a case, another pin grooves 53 extended spaced by a constant distance from the heat corresponding to the lower side can be installed as shown in FIG. 18.

The portion where the extendingly installed pin grooves 53 are located may be used as a boundary to wind the heating wire. By doing so, the distribution of the heating wire is increased, so that it is possible to increase the temperature of the lower side.

While the present invention has been described and illustrated herein with reference to the preferred embodiments thereof, it will be apparent to those skilled in the art that various modifications and variations can be made therein without departing from the spirit and scope of the invention. Thus, it is intended that the present invention covers the modifications and variations of this invention that come within the scope of the appended claims and their equivalents.

### INDUSTRIAL APPLICABILITY

As described above, according to the linear evaporation source of the present invention, when thin films are formed by a deposition process, a low material use rate of the vacuum evaporation source is improved, thickness uniformity throughout the whole area of the thin film as deposited is secured, and shadow effect due to the shadow mask is also improved.

In addition, according to the heating wire fixing device and method of the present invention, the damage of the heating wire is prevented and it is possible to install the heating wire around the evaporation source. Further, heat is uniformly applied to the evaporation source, endurance property of the heating wire is improved, and the area shielded by the insulation fixing plate is minimized to enhance the efficiency.

1. A linear evaporation source used for forming a thin film for an organic semiconductor device, the linear evaporation source comprising a crucible having a receiving space formed therein, for accommodating an evaporation material and an opening section formed at one side of the crucible in a length direction,
wherein the opening section becomes narrow as it travels from both ends to a center portion thereof.

2. The linear evaporation source of claim 1,
wherein the center portion of the opening section is partially closed in the length direction.

3. The linear evaporation source as in claim 1, further comprising a splash preventive section formed at a lower portion of the opening within the receiving space, for preventing the evaporation material from being discharged to an outside.

4. The linear evaporation source as in claim 1, further comprising a plurality of blocks arranged at regular intervals in the length direction within the receiving space, for dividing the receiving space and receiving the evaporation material therein.

5. A linear evaporation source used for forming a thin film for an organic semiconductor device, the linear evaporation source comprising a crucible having a receiving space formed therein, for accommodating an evaporation material and an opening section formed at one side of the crucible in a length direction,
wherein the opening section is spaced apart by a predetermined interval from each other in the length direction.

6. The linear evaporation source as in claim 5, further comprising a splash preventive section formed at a lower portion of the opening within the receiving space, for preventing the evaporation material from being discharged to an outside.

7. The linear evaporation source as in claim 5, further comprising a plurality of blocks arranged at regular intervals in the length direction within the receiving space, for dividing the receiving space and receiving the evaporation material therein.

8. A linear evaporation source used for forming a thin film for an organic semiconductor device, the linear evaporation source comprising a crucible having a receiving space formed therein, for accommodating an evaporation material and an opening section formed at one side of the crucible in a length direction,
wherein the opening section comprises:
a main opening having the same width in the length direction; and
triangular auxiliary openings arranged at both sides of the opening section and each of which width decreases at a remaining portion except for a predetermined portion of the center portion as it travels to the center portion.

9. The linear evaporation source as in claim 8, further comprising a splash preventive section formed at a lower portion of the opening within the receiving space, for preventing the evaporation material from being discharged to an outside.

10. The linear evaporation source as in claim 8, further comprising a plurality of blocks arranged at regular intervals in the length direction within the receiving space, for dividing the receiving space and receiving the evaporation material therein.

11. A linear evaporation source used for forming a thin film for an organic semiconductor device, the linear evaporation source comprising:
a crucible having a receiving space for accommodating an evaporation material therein and of which one side is opened; and
an opening adjusting unit having an opening of which width becomes narrow as it travels from both ends to the center portion, the opening adjusting unit being separatably inserted into the crucible at the one side.

12. The linear evaporation source of claim 11, wherein the crucible is partly removed at an overlapping portion with the opening adjusting unit so that a part of the opening adjusting unit is exposed to a heating source.

13. The linear evaporation source as in claim 11, further comprising a splash preventive section formed at a lower portion of the opening within the receiving space, for preventing the evaporation material from being discharged to an outside.

14. The linear evaporation source as in claim 11, further comprising a plurality of blocks arranged at regular intervals in the length direction within the receiving space, for dividing the receiving space and receiving the evaporation material therein.

15. A linear evaporation source used for forming a thin film for an organic semiconductor device, the linear evaporation source comprising a crucible having a receiving space formed therein, for accommodating an evaporation material and an opening section formed at one side of the crucible in a length direction,
wherein the opening section is formed such that width thereof becomes narrow as it travels from both ends to the center portion, and
wherein the crucible further comprises a splash preventive section formed protrudedly from a lower side portion of the opening within the receiving space.

16. A linear evaporation source assembly used for forming a thin film for an organic semiconductor device, the linear evaporation source assembly comprising:
a crucible having a receiving space formed therein, for accommodating an evaporation material and an opening section formed at one side of the crucible in a length direction; and
a heating unit installed to be associated with the crucible, for evaporating the evaporation material,
wherein the opening section is formed such that width thereof becomes narrow as it travels from both ends to the center portion.

17. An insulation fixing plate for fixing a heating wire in a deposition evaporation source, the insulation fixing plate comprising:
a frame forming a closed loop; and
a plurality of protrusions formed integrally with and protrudedly from the frame toward the center of the frame, the plurality of protrusions being spaced apart by regular clearances from one another,
wherein each of the plurality of protrusions has a groove formed in an upper surface thereof and on which a heating wire is hung.

18. The insulation fixing plate of claim 17, wherein the frame has a passing groove through which the heating wire passes at a portion of the clearance which meets with the groove.

19. The insulation fixing plate of claim 17, further comprising: a hanging jaw formed at an outer end of the frame; and a radiation plate of which both ends are fixed between the hanging jaw and the outer end.

20. A heater assembly of a deposition evaporation source comprising:
a pair of insulation fixing plates arranged apart by a constant interval from each other in a longitudinal direction, for fixing a heating wire in an evaporation source for a deposition, the insulation fixing plate including: (a) a frame forming a closed loop; and (b) a plurality of protrusions formed integrally with and protrudedly from the frame toward the center of the frame, the plurality of protrusions being spaced apart by regular clearances from one another, wherein each of the plurality of protrusions has a groove formed in an upper surface thereof and on which a heating wire is hung;
a heating wire passing through the clearances of the pair of insulation fixing plates and wound in a zigzag in upward and downward directions with the grooves as a boundary.

21. The heater assembly of claim 20, further comprising: a hanging jaw formed at an outer end of the frame; and a radiation plate of which both ends are fixed between the hanging jaw and the outer end.

22. A heating wire winding plate of a deposition evaporation source, which is provided such that the heating wire is wound on the insulation fixing plate of claim 17, the heating wire winding plate comprising a plurality pairs of pin grooves into which pins are inserted and arranged in two columns at regular intervals,
wherein the pin grooves arranged in one column are arranged in a zigzag to face regions between the pin grooves in the other column, and the width between the pin grooves corresponds to the width of the protrusion of the insulation fixing plate.

23. The heating wire winding plate of claim 22, further comprising another pin grooves extended and spaced by a predetermined distance from either one of the two columns.

24. The heating wire winding plate of claim 22, further comprising a fixing groove formed adjacent to the pin grooves formed at an end thereof and into which a fixing piece for fixing a front end of the heating wire is inserted.

25. A method for fixing a heating wire of a deposition evaporation source, the heating wire being installed at and fixed to the evaporation source by using the insulation fixing plate of claim 19 and the heating wire winding plate of claim 24, the method comprising the steps of:
inserting the pins into the pin grooves of the heating wire winding plate and fixing the front end of the heating wire at a position adjacent to the pin on which the heating wire is wound for the first time;
winding the heating wire in a zigzag between one column and another column facing the one column with the inserted pins as a boundary;
separating the winding-completed heating wire from the heating wire winding plate;
hanging bent portions of the separated heating wire on the grooves of the protrusions of the insulation fixing plate; and
pulling and arranging the pair of insulation fixing plates on which the heating wire is wound so as to have a constant tension, and installing the pair of insulation fixing plates at the evaporation source.

26. The method of claim 25, after the step of installing the pair of insulation fixing plates at the evaporation source, further comprising the step of installing a radiation plate between the pair of insulation fixing plates in an outward direction of the heating wire.

27. A linear evaporation source assembly used for forming a thin film for an organic semiconductor device, the linear evaporation source assembly comprising:
a crucible having a receiving space formed therein, for accommodating an evaporation material and an opening section formed at one side of the crucible in a length-direction;
a pair of insulation fixing plates arranged apart by a constant interval from each other in a longitudinal direction, for fixing a heating wire in an evaporation source for a deposition, the insulation fixing plate including: (a) a frame forming a closed loop; and (b) a plurality of protrusions formed integrally with and protrudedly from the frame toward the center of the frame, the plurality of protrusions being spaced apart by regular clearances from one another, wherein each of the plurality of protrusions has a groove formed in an upper surface thereof and on which a heating wire is hung; and
a heating wire passing through the clearances of the pair of insulation fixing plates and wound in a zigzag in upward and downward directions with the grooves as a boundary.
